(19) United States
(12) Patent Application Publication
(10) Pub. No.: US 2007/0252158 A1
(43) Pub. Date: Nov. 1, 2007

(54) Semiconductor light-emitting device and method of manufacturing the same

(75) Inventors: Yukari Inoguchi, Kitakatsuragi-Gun (JP); Nobuyuki Watanabe, Mihara-Shi (JP); Tetsuroh Murakami, Mihara-Shi (JP); Taeko Chiba, Nara-Shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/790,595

(22) Filed: Apr. 26, 2007

(30) Foreign Application Priority Data
Apr. 28, 2006 (JP) 2006-125169

(51) Int. Cl. H01L 33/00

(52) U.S. Cl. 257/79

(57) ABSTRACT

A semiconductor light-emitting device has a first conductivity type semiconductor layer, a luminous layer formed on the first conductivity type semiconductor layer, a second conductivity type semiconductor layer formed on the luminous layer, and a transmissive semiconductor layer formed on the second conductivity type semiconductor layer. The transmissive semiconductor layer is pervious to light coming from the luminous layer. The second conductivity type semiconductor layer and the transmissive semiconductor layer have different carrier concentrations, and the carrier concentration of the second conductivity type semiconductor layer is higher than the carrier concentration of the transmissive semiconductor layer.

This nonprovisional application claims priority under 35 U.S.C. §119(a) on Patent Application No. 2006-125169 filed in Japan on Apr. 28, 2006, the entire contents of which are hereby incorporated by reference.

### BACKGROUND OF THE INVENTION

The present invention relates to a semiconductor light-emitting device which is an illuminant used for, for example, a communication device, a road, rail way, or guide display panel device, an advertisement display device, a mobile telephone, a display backlight, lighting equipment, or the like, and a method of manufacturing the semiconductor light-emitting device.

In recent years, technologies of manufacturing a semiconductor light-emitting diode (referred to as an “LED” hereinafter), which is one of semiconductor light-emitting devices, have rapidly progressed, and in particular, LEDs for primary colors of light have been completed after the blue LED was developed, so that it has become possible to produce light of every wavelength by combinations of LEDs for primary colors of light. As a result of this, the scope of application of LEDs has been rapidly widened, and in particular, in the field of lighting, attention is being given to an LED as a natural-light or white-light source which is an alternative to an electric bulb or fluorescent lamp, with the increase of awareness of environmental and energy issues.

However, current LEDs are inferior in efficiency of conversion of applied energy into light as compared with an electric bulb or fluorescent lamp, and therefore research aimed at developing LEDs having a higher conversion efficiency and higher luminance has been underway whatever their wavelengths.

Until a decade ago, the focus of the research and development of a higher luminance LED has been on epitaxial growth technologies. However, in recent years when the technologies have matured, the focus is being sifted to the development which centers on process technologies.

Increase in luminance by a process technology means increase in external quantum efficiency (i.e., an internal quantum efficiency multiplied by an external extraction efficiency), and specifically there are process technologies such as technologies for micromachining the shape of an LED, providing reflecting films and transparent electrodes, etc. Among others, some techniques of increasing the luminance by wafer bonding have been established for red and blue LEDs, and high luminance LEDs were invented and have appeared on the market.

One of such techniques using the wafer bonding is a technique of attaching a substrate transparent to an emission wavelength, such as a glass substrate, a sapphire substrate, or a GaP substrate, to an epitaxial layer directly.

FIG. 1 is a schematic cross-sectional view of an LED for which the technique was used.

In FIG. 1, the reference numeral 201 denotes a window layer, 202 and 204 denote epitaxial layers, 203 denotes a luminous layer, 205 denotes a transparent substrate, and 206 and 207 denote electrodes.

In the LED in FIG. 1, light L emitted from the luminous layer 203 passes through as shown by the arrows without being absorbed by the transparent substrate 205.

In particular, in the LED for which the technique of attaching the transparent substrate 205 directly to the epitaxial layer 204 is used, light emitted from the luminous layer 203 can be extracted from almost every surface of the LED without passing through the luminous layer 203 again, in other words, without being absorbed by the luminous layer 203. It is therefore possible to develop an LED having a higher conversion efficiency (light extraction efficiency).

One of conventional techniques of attaching a transparent substrate to an epitaxial layer is described in JP 3230638 B2. In the technique described in JP 3230638 B2, a GaP (gallium phosphorus) transparent substrate is attached directly to an AlGaInP (aluminum gallium indium phosphorus) semiconductor layer in order to make a 4-element LED.

However, it has been found out that the technique of directly attaching a transparent substrate to an epitaxial layer as described above has a problem that when the carrier concentration of the transparent substrate (substrate concentration) is high, absorption of light by free carriers occurs in the transparent substrate, so that emitted light cannot be extracted sufficiently.

### SUMMARY OF THE INVENTION

In order to solve the above problem, the applicant/assignee (Sharp Kabushiki Kaisha) of the present application proposed, in previously filed U.S. application Ser. No. 11/492,045, a method of suppressing segregation of dopant atoms to the attachment interface or surface by reducing the carrier concentration of the transparent substrate, to thereby prevent the formation of a light absorption layer and not reduce the luminous efficiency, and a method of reducing light absorption caused by free carriers in the transparent substrate so as not to reduce the luminous efficiency. FIG. 2 is a schematic view of an LED to which such a method is applied. In FIG. 2, reference numerals 301 and 303 denote epitaxial layers, reference numeral 302 denotes a luminous layer, and reference numeral 304 denote a transparent substrate.

According to the above methods, the segregation of dopant atoms to the attachment surface of the transparent substrate 304 is suppressed, and thereby the light transmittance at the attachment interface of the transparent substrate 304 is prevented from decreasing.

In addition, in the above methods, the carrier concentration of the transparent substrate 304 does not become high, so that the quantity of light absorbed by free carriers in the transparent substrate 304 is reduced and the luminous efficiency is thus not reduced.

However, limiting the carrier concentration of the transparent substrate 304 as in the above methods causes a problem that the yield of the transparent substrate 304 decreases and the manufacturing cost thus increases.

It is therefore an object of the present invention to provide a semiconductor light-emitting device which has a high luminous efficiency and can be manufactured with a low cost, and a method of manufacturing it.

In order to accomplish the above object, a semiconductor light-emitting device according to an aspect of the present invention includes:

a first conductivity type semiconductor layer;

a luminous layer formed on the first conductivity type semiconductor layer;

a second conductivity type semiconductor layer formed on the luminous layer; and

a transmissive semiconductor layer which is formed on the second conductivity type semiconductor layer and is pervious to light coming from the luminous layer, wherein

the second conductivity type semiconductor layer and the transmissive semiconductor layer have different carrier concentrations, and the carrier concentration of the second conductivity type semiconductor layer is higher than the carrier concentration of the transmissive semiconductor layer.

In the present invention, the “first conductivity type” means a p type or an n type, and the “second conductivity type” means the n type when the first conductivity type is the p type, and means the p type when the first conductivity type is the n type.

FIG. 3 is a conceptual diagram showing a basic structure of a semiconductor light-emitting device according to the present invention. However, a transmissive semiconductor substrate 405 shown in the figure is not an essential component for the semiconductor light-emitting device according to the present invention. The function and effect of the semiconductor light-emitting device according to the present invention will be described below with reference to FIG. 3. The carrier concentration of the second conductivity type semiconductor layer 403 is larger than the carrier concentration of the transmissive semiconductor layer 404, so that the diffusion of carriers from the transmissive semiconductor layer 404 to the second conductivity type semiconductor layer 403 is suppressed, and therefore the segregation of dopant atoms to a luminous layer 402 side of the transmissive semiconductor layer 404 is also suppressed. As a result, the light transmittance of the transmissive semiconductor layer 404 is prevented from decreasing.

Furthermore, even if the carrier concentration of the transmissive semiconductor substrate 405 for forming the transmissive semiconductor layer 404 is relatively high, the carrier concentration of the transmissive semiconductor layer 404 between the transmissive semiconductor substrate 405 and the second conductivity type semiconductor layer 403 is kept low, so that the quantity of light absorbed by free carriers in the transmissive semiconductor layer 404 is reduced and the luminous efficiency is thus prevented from decreasing.

Because of this, it is not necessary to limit the carrier concentration of the transmissive semiconductor substrate 405 in order to prevent the luminous efficiency of the semiconductor light-emitting device from decreasing, so that the yield of the transmissive semiconductor substrate 405 is prevented from decreasing and the manufacturing cost can be thus reduced.

In this connection, the transmissive semiconductor substrate 405 may be removed after forming the first conductivity type semiconductor layer 401, the luminous layer 402, the second conductivity type semiconductor layer 403, and the transmissive semiconductor layer 404. In other words, the semiconductor light-emitting device according to the present invention may or may not comprise the transmissive semiconductor substrate 405.

The transmissive semiconductor layer may be attached to the second conductivity type semiconductor layer directly or indirectly via adhesive, metal, oxide, nitride, and/or the like.

Also in the case that the transmissive semiconductor layer is attached to the second conductivity type semiconductor layer indirectly via adhesive, metal, oxide, nitride, and/or the like, light absorption by free carriers is reduced.

Needless to say, the adhesive, metal, oxide, nitride, and/or the like should be at least partially pervious to light from the luminous layer.

Furthermore, the number of layers provided between the transmissive semiconductor layer and the second conductivity type semiconductor layer may be one or more.

In one embodiment, the semiconductor light-emitting device further includes a transmissive semiconductor substrate which is formed on the transmissive semiconductor layer and is pervious to light coming from the luminous layer, and the carrier concentration of the transmissive semiconductor layer is higher than that of the transmissive semiconductor substrate.

In one embodiment, the carrier concentration of the transmissive semiconductor layer is 2.5×10¹⁸ cm⁻³ or less.

In this embodiment, the light absorption by free carriers can be held down.

In one embodiment, the carrier concentration of the transmissive semiconductor layer is between 2.5×10¹⁷ cm⁻³ and 8.0×10¹⁷ cm³, inclusive.

In this embodiment, due to the effect of preventing the light transmittance of the transmissive semiconductor layer from decreasing, the effect of increasing the luminous efficiency can be obtained with reliability.

The lower limit of the carrier concentration of the transmissive semiconductor layer is a value that allows ohmic contact to be established when an electrode is formed in a device fabrication process.

FIG. 4A shows an experimental result about a low concentration p-type GaP semiconductor layer having a carrier concentration of 5.0×10¹⁷ cm⁻³ which is an example of the transmissive semiconductor layer. FIG. 4B shows an experimental result about a high concentration p-type GaP semiconductor layer having a carrier concentration of 1.5×10¹⁸ cm⁻³ which is also an example of the transmissive semiconductor layer. The p-type GaP semiconductor layer in FIGS. 4A and 4B is attached to a p-type GaP contact layer, which is an example of the second conductivity type semiconductor layer, and the p-type GaP semiconductor layer is zinc-doped.

As understood from FIGS. 4A and 4B, the number of Zn atoms segregated to an attachment interface between the p-type GaP semiconductor layer and the p-type GaP contact layer can be more reduced when the carrier concentration of the p-type GaP semiconductor layer is reduced than when the carrier concentration of the p-type GaP semiconductor is increased. In other words, light absorption at the attachment interface can be reduced.

FIG. 5 shows the light transmittances of the low concentration and high concentration p-type GaP semiconductor layers shown in FIGS. 4A and 4B measured when they are used alone. In these light transmittances, reflection of incident light at various interfaces is not at all taken into account, so that light transmittances at energy bands lower than the band gaps of the p-type GaP semiconductor layers are in the neighborhood of 50% (actual light transmittances are approximately 90% or more).

As understood from FIG. 5, when the wavelength of light incident on the p-type GaP semiconductor layer is in the range of about 550 nm to 700 nm, the light transmittance can be more increased when the carrier concentration of the p-type GaP semiconductor is reduced than when the carrier concentration of the p-type GaP semiconductor is increased.

In one embodiment, the semiconductor light-emitting device further includes a second conductivity type intermediate layer disposed between the luminous layer and the second conductivity type semiconductor layer, and the carrier concentration of the second conductivity type semiconductor layer is higher than that of the second conductivity type intermediate layer.

In the semiconductor light-emitting device of this embodiment, the carrier concentration of the second conductivity type intermediate layer, which is nearer the luminous layer than the second conductivity type semiconductor layer, is lower than this second conductivity type semiconductor layer, thereby preventing the diffusion of carriers to the luminous layer.

In addition, a carrier diffusion preventing layer may be provided between the intermediate layer and the luminous layer, and when the carrier diffusion preventing layer is provided, the effect of preventing the diffusion of carriers to the luminous layer is enhanced.

The carrier diffusion preventing layer may have a carrier concentration lower than the carrier concentration of the intermediate layer.

In one embodiment, the transmissive semiconductor layer has a thickness of 0.5 μm or more.

In the semiconductor light-emitting device of this embodiment, even if high-temperature heat treatment is carried out on the transmissive semiconductor layer and a substrate for forming it, for example, a transmissive semiconductor substrate, the dopant atoms of the transmissive semiconductor substrate can be prevented from passing through the transmissive semiconductor layer.

As a matter of fact, the minimum thickness value of the transmissive semiconductor layer is dependent on the temperature and time of the heat treatment given to the transmissive semiconductor substrate and the transmissive semiconductor layer, and the carrier concentrations of the transmissive semiconductor substrate and the transmissive semiconductor layer.

In one embodiment, the semiconductor light-emitting device further includes a transmissive semiconductor substrate which is formed on the transmissive semiconductor layer and is pervious to light coming from the luminous layer, and at least one of the transmissive semiconductor layer and the transmissive semiconductor substrate is made of first conductivity type semiconductor.

In one embodiment, the transmissive semiconductor layer is made of second conductivity type semiconductor.

In the semiconductor light-emitting device of this embodiment, the transmissive semiconductor layer has the same polarity as the second conductivity type semiconductor layer, thereby being electrically connectable to the second conductivity type semiconductor layer.

Because of this, an electrode for making the luminous layer emit light can be formed on the transmissive semiconductor layer.

In one embodiment, the semiconductor light-emitting device further includes a transmissive semiconductor substrate which is formed on the transmissive semiconductor layer and is pervious to light coming from the luminous layer, and the transmissive semiconductor substrate is made of first conductivity semiconductor.

In one embodiment, the first conductivity type semiconductor layer, the luminous layer, and the second conductivity type semiconductor layer each contain at least two of gallium, aluminum, indium, phosphorus, arsenic, zinc, tellurium, sulfur, nitrogen, silicon, carbon, and oxygen.

In the semiconductor light-emitting device of this embodiment, the emission wavelength of the luminous layer can be selected from a wide range of from an infrared region to a near-ultraviolet region.

In one embodiment, the transmissive semiconductor layer has a thickness of 70 μm or more.

In the semiconductor light-emitting device of this embodiment, even if the transmissive semiconductor substrate, for example, for forming the transmissive semiconductor layer is removed, the strength of the device can be kept by the transmissive semiconductor layer only.

Furthermore, if the transmissive semiconductor substrate has carriers at a high concentration, light absorption can be held down to a minimum value by completely removing the transmissive semiconductor substrate, and thereby a device having an improved light extraction efficiency can be manufactured.

In one embodiment, the semiconductor light-emitting device further includes a transmissive semiconductor substrate which is formed on the transmissive semiconductor layer and is pervious to light coming from the luminous layer, and the transmissive semiconductor layer and the transmissive semiconductor substrate are of different conductivity types.

In other words, in the semiconductor light-emitting device of this embodiment, the conductivity type of the transmissive semiconductor layer may be the first conductivity type and the conductivity type of the transmissive semiconductor substrate may be the second conductivity type, or, the conductivity type of the transmissive semiconductor layer may be the second conductivity type and the conductivity type of the transmissive semiconductor substrate may be the first conductivity type.

In the semiconductor light-emitting device of this embodiment, the conductivity type of the transmissive semiconductor substrate may be selected from many alternatives including p-type, n-type, and non-dope type, which provides the advantage that it is possible to use a low manufacturing cost conductivity type substrate as the transmissive semiconductor substrate. Even if the low manufacturing cost conductivity type substrate is a growth substrate which is opposite in polarity to the transmissive semiconductor layer, there is no problem because the substrate is removed away in the device or chip fabrication process.

A method of manufacturing a semiconductor light-emitting device, according to another aspect of the present invention, includes steps of:

fabricating a first wafer by stacking layers including at least a first conductivity type semiconductor layer, a luminous layer, and a second conductivity type semiconductor layer on a first conductivity type semiconductor substrate;

fabricating a second wafer by forming a transmissive semiconductor layer on a transmissive semiconductor substrate which is pervious to light coming from the luminous layer, said transmissive semiconductor layer having a carrier concentration lower than a carrier concentration of the second conductivity type semiconductor layer and being pervious to light coming from the luminous layer;

joining the second wafer to the first wafer by first placing the second wafer on the first wafer in such a manner that the transmissive semiconductor layer is opposed to the second conductivity type semiconductor layer and then heating the first and second wafers while pressing the second wafer against the first wafer; and

removing the first conductivity type semiconductor substrate.

The above method can fabricate a semiconductor light-emitting device having the above-described functions and effects. Specifically, because the carrier concentration of the second conductivity type semiconductor layer is higher than the carrier concentration of the transmissive semiconductor layer, the diffusion of carriers from the transmissive semiconductor layer to the second conductivity type semiconductor layer is suppressed, and therefore the segregation of dopant atoms to a luminous layer side of the transmissive semiconductor layer is also suppressed. As a result, the light transmittance of the transmissive semiconductor layer is prevented from decreasing.

Also, because the carrier concentration of the second conductivity type semiconductor layer is higher than the carrier concentration of the transmissive semiconductor layer, that is, because the carrier concentration of the transmissive semiconductor layer is lower than the carrier concentration of the second conductivity type semiconductor layer, light absorption by the free carriers in the transmissive semiconductor layer decreases and the luminous efficiency is improved accordingly.

Furthermore, even if the carrier concentration of the transmissive semiconductor substrate for forming the transmissive semiconductor layer is relatively high, the carrier concentration of the transmissive semiconductor layer between the transmissive semiconductor substrate and the second conductivity type semiconductor layer is kept low, so that the quantity of light absorbed by free carriers in the transmissive semiconductor layer is reduced and the luminous efficiency is thus prevented from decreasing.

According to the present invention, it is not necessary to limit the carrier concentration of the transmissive semiconductor substrate in order to prevent the luminous efficiency of the semiconductor light-emitting device from decreasing, so that the yield of the transmissive semiconductor substrate does not decrease and the manufacturing cost can be thus reduced.

Furthermore, any conductivity type may be applied to the transmissive semiconductor substrate, so that a less expensive semiconductor substrate may be used as the transmissive semiconductor substrate.

As described above, the transmissive semiconductor layer may be attached to the second conductivity type semiconductor layer directly or indirectly via adhesive, metal, oxide, nitride, and/or the like.

Needless to say, the adhesive, metal, oxide, nitride, and/or the like should be at least partially pervious to light from the luminous layer.

Furthermore, the number of layer provided between the transmissive semiconductor layer and the second conductivity type semiconductor layer may be one or more.

The thickness of the transmissive semiconductor layer is optimized according to the materials of the semiconductor light-emitting device and the manufacturing processes.

In one embodiment, after joining the second wafer to the first wafer, the transmissive semiconductor substrate is removed.

In one embodiment, the transmissive semiconductor layer is formed by a liquid phase epitaxial method or a chemical vapor deposition (CVD) method.

The liquid phase epitaxial method and the CVD method are both suitable to form a thick semiconductor layer, and are thus able to form the transmissive semiconductor layer thick.

In one embodiment, the transmissive semiconductor layer is made by a metal organic chemical vapor deposition (MOCVD) method.

In this embodiment, use of the MOCVD method in forming the transmissive semiconductor layer enables an easy control of the carrier concentration of the transmissive semiconductor layer. As a result, a device having a steady characteristic can be obtained.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic cross-sectional view of a conventional LED;

FIG. 2 is a conceptual illustration showing a basic configuration of an LED that can solve the problem inherent in the above conventional LED;

FIG. 3 is a conceptual diagram showing a basic structure of a semiconductor light-emitting device according to the present invention;

FIG. 4A is a graph showing the distribution in the depth direction of zinc concentration at the attachment interface of a GaP semiconductor layer having a low carrier concentration;

FIG. 4B is a graph showing the distribution in the depth direction of zinc concentration at the attachment interface of a GaP semiconductor layer having a high carrier concentration;

FIG. 5 is a graph showing the relation between the wavelength of light incident on a GaP substrate and the light transmittance of the GaP substrate;

FIG. 6A is a schematic cross-sectional view of an LED according to a first embodiment of the present invention;

FIG. 6B is a schematic cross-sectional view of a variation of the LED of the first embodiment;

FIG. 7A shows a process step for manufacturing the LED of the first embodiment;

FIG. 7B shows a process step for manufacturing the LED of the first embodiment;

FIG. 8 is a schematic cross-sectional view of a jig used for manufacturing LEDs of the first and second embodiments of the present invention; and

FIG. 9 is a schematic cross-sectional view of the LED of the second embodiment of the present invention.

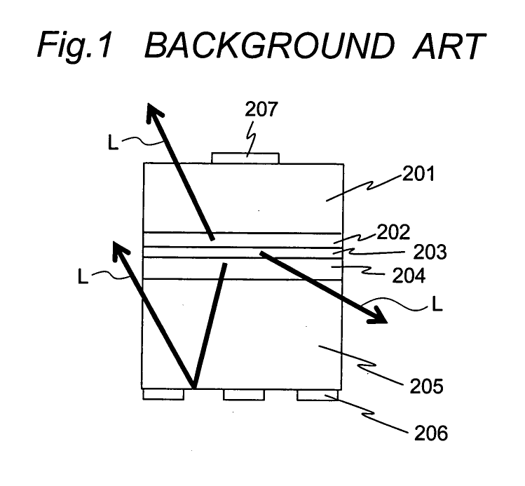

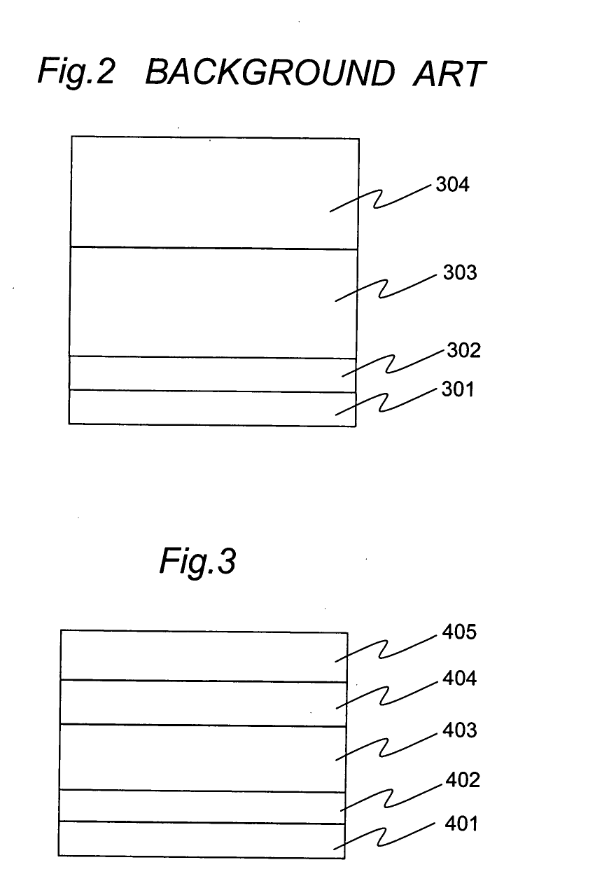

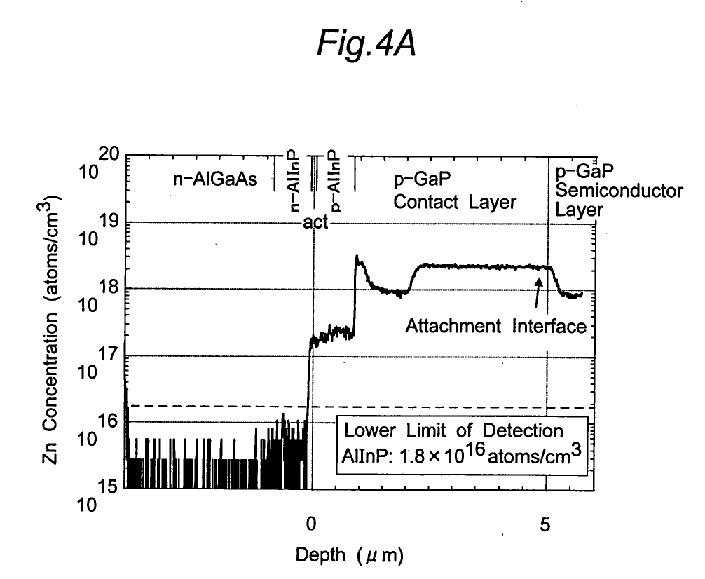

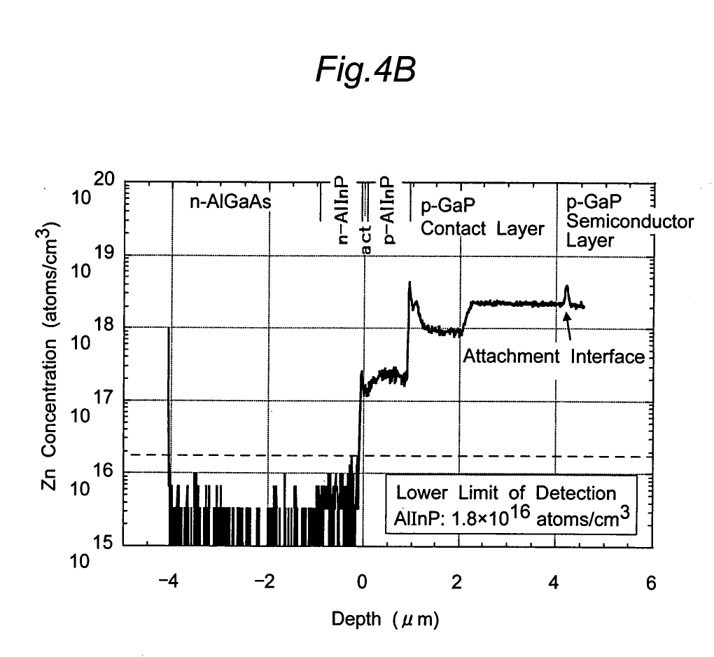

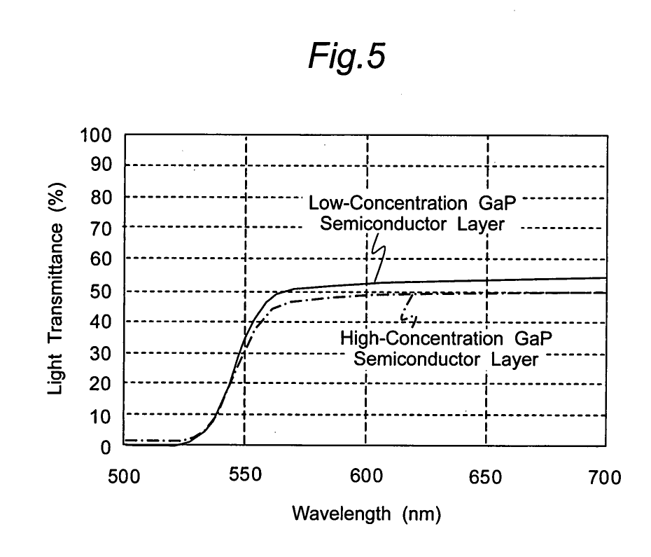

### DETAILED DESCRIPTION OF THE INVENTION

The light-emitting device of the present invention will be described below according to the embodiments shown in the figures.

### First Embodiment

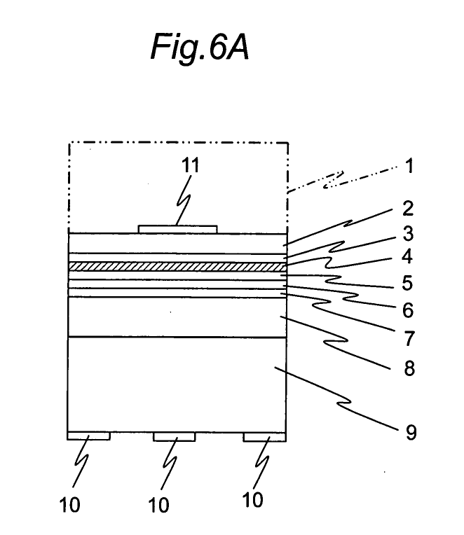

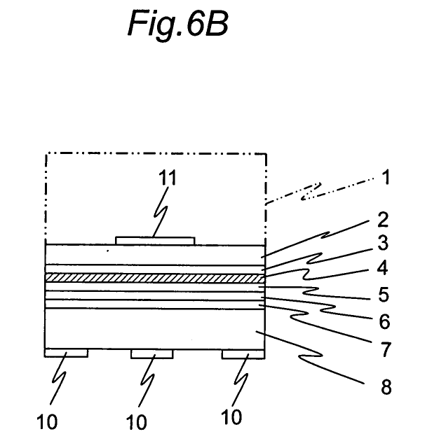

FIG. 6A is a schematic cross-sectional view of the LED of the first embodiment of the present invention.

The LED has an AlGaInP 4-element active layer 4 which has an emission wavelength for a red color. This AlGaInP active layer 4 is an example of the luminous layer.

The LED also has an n-type Al_{0.6}Ga_{0.4}As current diffusion layer 2 and an n-type Al_{0.5}In_{0.5}P cladding layer 3 on the upper side, as viewed in the figure, of the AlGaInP active layer 4. Further, the LED has a p-type Al_{0.5}In_{0.5}P cladding layer 5, a p-type GaInP intermediate layer 6, a p-type GaP contact layer 7, a p-type GaP light-transmissive semiconductor layer 8, and a p-type GaP light-transmissive substrate 9 under the AlGaInP active layer 4 in the figure. The n-type Al_{0.6}Ga_{0.4}As current diffusion layer 2 is an example of the first conductivity type semiconductor layer. The p-type GaInP intermediate layer 6 is an example of the intermediate layer. The p-type GaP contact layer 7 is an example of the second conductivity type semiconductor layer. The p-type GaP light-transmissive semiconductor layer 8 is an example of the transmissive semiconductor layer. The p-type GaP light-transmissive substrate 9 is an example of the transmissive semiconductor substrate.

The p-type GaP light-transmissive semiconductor layer 8 and the p-type GaP light-transmissive substrate 9 are attached to the p-type GaP contact layer 7.

An electrode 11 is provided on the upper side of the n-type Al_{0.6}Ga_{0.4}As current diffusion layer 2, and another electrode 10 is provided on the underside of the p-type GaP light-transmissive substrate 9. The electrode 11 was formed, after an n-type GaAs substrate 1 is removed, on an exposed upper surface of the n-type Al_{0.6}Ga_{0.4}As current diffusion layer 2.

A method of manufacturing the LED will be described below.

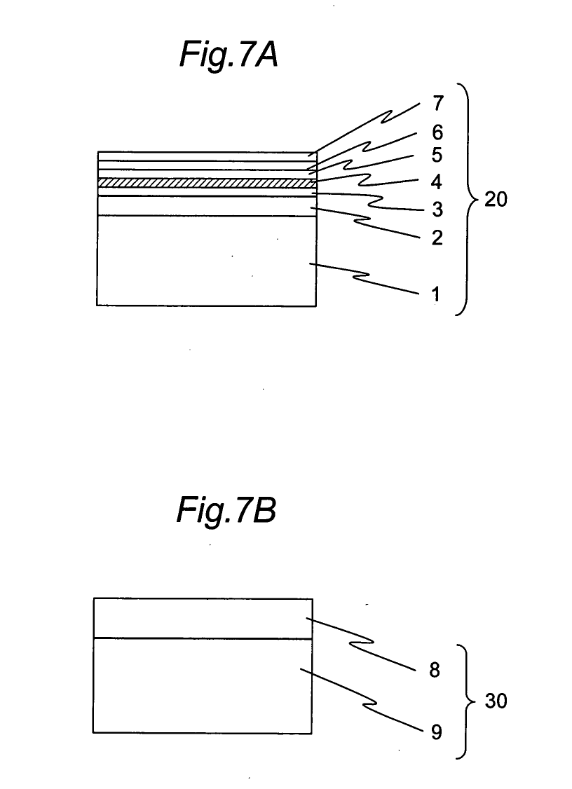

At first, by using a MOCVD method, an LED wafer 20 is made in which as shown in FIG. 7A, an Al_{0.6}Ga_{0.4}As current diffusion layer 2, an n-type Al_{0.5}In_{0.5}P cladding layer 3, an AlGaInP active layer 4, a p-type Al_{0.5}In_{0.5}P cladding layer 5, a p-type GaInP intermediate layer 6, and a p-type GaP contact layer 7 are staked in this order on an n-type GaAs substrate 1. The LED wafer 20 is an example of the first wafer.

The AlGaInP active layer 4 has a quantum well structure. In more detail, the AlGaInP active layer 4 is formed by stacking alternately (Al_{0.05}Ga_{0.95})_{0.5}In_{0.5}P well layers and (Al_{0.5}Ga_{0.5})_{0.5}In_{0.5}P barrier layers. The number of pairs of the well layer and the barrier layer is 10.

Thicknesses of the substrate and the layers are: 250 μm of the n-type GaAs substrate 1; 5.0 μm of the Al_{0.6}Ga_{0.4}As current diffusion layer 2; 1.0 μm of the n-type Al_{0.5}In_{0.5}P cladding layer 3; 0.5 μm of the AlGaInP active layer 4; 1.0 μm of the p-type Al_{0.5}In_{0.5}P cladding layer 5; 1.0 μm of the p-type GaInP intermediate layer 6; and 4.0 μm of the p-type GaP contact layer 7.

In the substrate and the layers, Si is used as an n-type dopant while Zn is used as a p-type dopant.

Carrier concentrations of the substrate and the layers are: 1.0×10¹⁸ cm⁻³ of the n-type GaAs substrate 1; 1.0×10¹⁸ cm⁻³ of the n-type Al_{0.6}Ga_{0.4}As current diffusion layer 2; 5×10¹⁷ cm⁻³ of the n-type Al_{0.5}In_{0.5}P cladding layer 3; the AlGaInP active layer 4 being non-doped; 5×10¹⁷ cm⁻³ of the p-type Al_{0.5}In_{0.5}P cladding layer 5; 1.0×10¹⁸ cm⁻³ of the p-type GaInP intermediate layer 6; and 2.0×10¹⁸ cm⁻³ of the p-type GaP contact layer 7.

Next, the LED wafer 20 is half-diced to form half-dicing grooves at a predetermined pitch on the epitaxial face of the wafer. The depth of the order of 10 to 50 μm of the half-dicing grooves is suitable to keep the strength of the LED wafer 20.

Next, as shown in FIG. 7B, a p-type GaP epitaxial layer serving as a p-type GaP light-transmissive semiconductor layer 8 is formed to a thickness of 10 μm or more on the p-type GaP light-transmissive substrate 9 by liquid phase epitaxy. That is, a light-transmissive wafer 30 consisting of the p-type GaP light-transmissive substrate 9 and the p-type GaP light-transmissive semiconductor layer 8 is prepared. The light-transmissive wafer 30 is an example of the second wafer.

The p-type GaP light-transmissive semiconductor layer 8 has a thickness of 100 μm and the p-type GaP light-transmissive substrate 9 has a thickness of 280 μm.

The p-type GaP light-transmissive semiconductor layer 8 has a carrier concentration of 5×10¹⁷ cm⁻³ and the p-type GaP light-transmissive substrate 9 has a carrier concentration of 5×10¹⁸ cm⁻³.

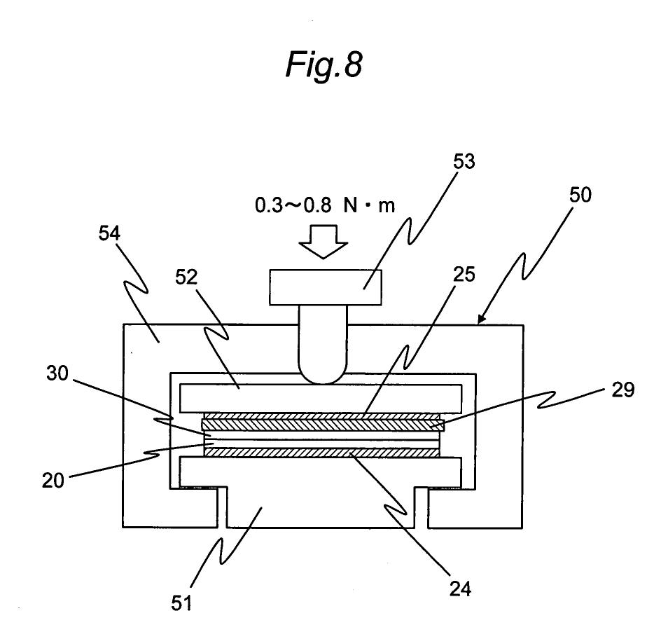

Next, the light-transmissive wafer 30 is joined directly to the LED wafer 20 such that the p-type GaP light-transmissive semiconductor layer 8 is in contact with the p-type GaP contact layer 7, by using a jig 50 shown in FIG. 8.

The jig 50 is made of quartz and has a base 51 for supporting the wafer 20, a presser board 52 for covering an upper surface, as viewed in FIG. 8, of the p-type GaP light-transmissive substrate 9, and a pusher 53 for pushing the presser board 52 by receiving a predetermined magnitude of force.

The pusher 53 is adapted to be guided in the vertical direction by a frame 54 substantially shaped like the symbol ] when viewed from the front side. The frame 54 is adapted to be engaged with the base 51 to transfer the force appropriately to the presser board 52 positioned between the base 51 and the pusher 53.

A carbon sheet 24 is disposed between the base 51 and the LED wafer 20, while a carbon sheet 25 and a pyrolytic boron nitride (PBN) board 29 are disposed between the presser board 52 and the light-transmissive wafer 30.

Using the jig 50, the p-type GaP light-transmissive semiconductor layer 8 and the p-type GaP contact layer 7 are brought into contact with each other, and the moment of force of 0.3 Nm-0.8 Nm, for example, is applied to the pusher 53 in order that compressive force acts on the contact interface between the p-type GaP light-transmissive semiconductor layer 8 and the p-type GaP contact layer 7. In this state, the LED wafer 20 and the light-transmissive wafer 30 are set in a heating furnace together with the jig 50 and are heated for 30 minutes at a temperature in the neighborhood of 800° C. in an atmosphere of hydrogen. As a result, the light-transmissive wafer 30 is directly joined to the LED wafer 20.

Next, the LED wafer 20 and the light-transmissive wafer 30 are cooled, and are then taken out from the heating furnace. After that, the n-type GaAs substrate 1 is dissolved away with the mixture of ammonia water, hydrogen peroxide, and water.

Next, a p-type electrode 10 is formed on the underside, as viewed in FIG. 8, of the p-type GaP light-transmissive substrate 9, while an n-type electrode 11 is formed on the upper side, as viewed in FIG. 8, of the Al_{0.6}Ga_{0.4}As current diffusion layer 2, and then dicing of the wafers is performed along the half-dicing grooves for chip splitting, to thereby obtain an LED as shown in FIG. 8.

AuBe/Au is selected as the material of the p-type electrode 10, while AuSi/Au is selected as the material of the n-type electrode 11. These materials are deposited on the wafer and patterned into predetermined shapes by photolithography and wet etching, to thereby obtain the p-type electrode 10 and the n-type electrode 11.

In the LED obtained as described above, the carrier concentration of the p-type GaP contact layer 7 is larger than the carrier concentration of the p-type GaP light-transmissive semiconductor layer 8, so that the diffusion of carriers from the p-type GaP light-transmissive semiconductor layer 8 to the p-type GaP contact layer 7 is suppressed, and therefore the segregation of dopant atoms to the AlGaInP active layer 4 side of the p-type GaP light-transmissive semiconductor layer 8 is also suppressed. As a result, the light transmittance of p-type GaP light-transmissive semiconductor layer 8 is prevented from decreasing.

Also, light absorption by free carriers in the p-type GaP light-transmissive semiconductor layer 8 is reduced, whereby the luminous efficiency is improved.

Furthermore, even if the carrier concentration of the p-type GaP light-transmissive substrate 9 is relatively high, the luminous efficiency is prevented from decreasing because the carrier concentration of the p-type GaP light-transmissive semiconductor layer 8 between the p-type GaP light-transmissive substrate 9 and the p-type GaP contact layer 7 is low.

For the above reasons, it is not necessary to limit the carrier concentration of the p-type GaP light-transmissive substrate 9 in order to prevent the luminous efficiency of the LED from decreasing, so that the yield of the p-type GaP light-transmissive substrate 9 is prevented from decreasing and the manufacturing cost can be thus reduced.

In the first embodiment, because the n-type GaAs substrate 1 absorbs the light from the AlGaInP active layer 4, the n-type GaAs substrate 1 has been removed. However, if an n-type substrate made of a material which does not absorb the light from the AlGaInP active layer 4 is used, it is not necessary to remove the n-type substrate.

Although the p-type GaP light-transmissive semiconductor layer 8 having the carrier concentration of 5.0×10¹⁷ cm⁻³ is used in the first embodiment, the carrier concentration of the p-type GaP light-transmissive semiconductor layer 8 used in the present invention is not limited to 5.0×10¹⁷ cm⁻³. In other words, a p-type GaP light-transmissive semiconductor layer having a carrier concentration of 2.5×10¹⁸ cm⁻³ or less may be used in the present invention.

Among the carrier concentration range of 2.5×10¹⁸ cm⁻³ or less for the p-type GaP light-transmissive layer, a carrier concentration within a range of from 5.0×10¹⁷ cm⁻³ to 8.0×10¹⁷ cm⁻³ is preferable.

Although the p-type GaP contact layer 7 having the carrier concentration of 2.0×10¹⁸ cm⁻³ is used in the first embodiment, the carrier concentration of the p-type GaP contact layer used in the present invention is not limited to 2.0×10¹⁸ cm⁻³. In other words, a p-type GaP contact layer having a carrier concentration in a range of from 5.0×10¹⁷ cm⁻³ to 5.0×10¹⁸ cm⁻³ may be used in the present invention.

It should be noted that even when the p-type GaP contact layer having a carrier concentration in a range of 5.0×10¹⁷ cm⁻³-5.0×10¹⁸ cm⁻³ is used, the carrier concentration of this contact layer should be higher than the p-type GaP semiconductor layer that is in contact with the contact layer.

Although the p-type GaInP intermediate layer 6 is provided between the p-type Al_{0.5}In_{0.5}P cladding layer 5 and the p-type GaP contact layer 7 in the first embodiment, the p-type Al_{0.5}In_{0.5}P cladding layer 5 may be in contact with the p-type GaP contact layer 7 without any intermediate layer therebetween.

Although the p-type GaP light-transmissive semiconductor layer 8 has a thickness of 100 μm in the first embodiment, the thickness of the p-type GaP light-transmissive semiconductor layer employed in the present invention is not limited to 100 μm. The present invention can use a p-type GaP light-transmissive semiconductor layer of a thickness of 0.5 μm or more.

Because the p-type GaP light-transmissive semiconductor layer 8 has a thickness of as large as 100 μm, the p-type GaP light-transmissive substrate 9 may be fully removed after the light-transmissive wafer 30 is attached directly to the LED wafer 20, to form an LED as shown in FIG. 6B.

The removal of the p-type GaP light-transmissive substrate 9 enables minimum light absorption and hence an increased light extraction efficiency.

The p-type GaP light-transmissive substrate 9 can be fully removed only when the p-type GaP light-transmissive semiconductor layer 8 has a thickness of not less than 70 μm. This is because, if the p-type GaP light-transmissive semiconductor layer 8 has a thickness of as large as 70 μm or more, the strength of the device can be kept by the p-type GaP light-transmissive semiconductor layer 8 only.

Although the p-type GaP light-transmissive substrate 9 has a thickness of 280 μm in the first embodiment, the thickness of the p-type GaP light-transmissive substrate employed in the present invention is not limited to 280 μm.

Although there is no layer provided between the n-type GaAs substrate 1 and the Al_{0.6}Ga_{0.4}As current diffusion layer 2 in the first embodiment, a buffer layer may be provided therebetween.

Also, although the light-transmissive wafer 30 is joined directly to the LED wafer 20 in the first embodiment, these wafers may be joined together via a material such as adhesive, metal, oxide, nitride, or the like. If such material is pervious to light, the material can be placed all over the wafer surface. If, however, such material is not pervious to light, the material should be locally placed on the wafer surface, in a scattered fashion for example.

### Second Embodiment

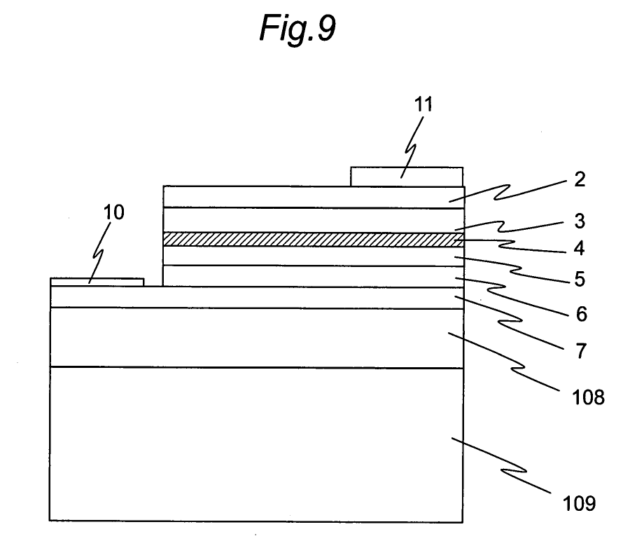

FIG. 9 is a schematic cross-sectional view of the LED of the second embodiment of the present invention. In FIG. 9, components identical in material and conductivity type to those of the first embodiment shown in FIG. 6 are denoted by reference numbers identical to those of the components in FIG. 6 regardless of shape, and description about the components is omitted. Because of this, shapes of components may be different between FIG. 6 and FIG. 9 even if identical reference numbers are attached to them.

The LED of this embodiment is different from the first embodiment in that the LED has an n-type GaP transmissive semiconductor layer 108 having a thickness of 70 μm and an n-type GaP transmissive substrate 109 having a thickness of 200 μm. The n-type GaP transmissive semiconductor layer 108 is an example of the transmissive semiconductor substrate, and the n-type GaP transmissive substrate 109 is an example of the transmissive semiconductor substrate.

The n-type GaP transmissive substrate 109 is pervious to light from the AlGaInP active layer 4. In other words, the n-type GaP transmissive substrate 109 is made of a semiconductor material which is pervious to the emission wavelength of the AlGaInP active layer 4.

A p-type GaInP intermediate layer 6-side surface of the p-type GaP contact layer 7 is partially exposed, and the electrode 10 is formed on the exposed surface. When the carrier concentration of the n-type GaP transmissive substrate 109 is high, the larger the thickness of the n-type GaP transmissive semiconductor layer 108 is, the less light is absorbed, and the luminous efficiency thus becomes higher. The n-type GaP transmissive semiconductor layer 108 is different from the p-type GaP transmissive semiconductor layer 8 in the first embodiment only in shape and conductivity type.

The LED configured as described above is able to have the same function and effects as the first embodiment. Also, the LED has the n-type GaP transmissive semiconductor layer 108 and the n-type GaP transmissive substrate 109. This is why the p-type GaP contact layer 7 is partially exposed and the electrode 10 is formed on the exposed surface.

Because the electrode 10 is formed on the exposed surface of the p-type GaP contact layer 7, and the electrode 11 is formed on the n-type Al_{0.6}Ga_{0.4}As current diffusion layer 2, wire bonding can be easily carried out on the electrodes 10 and 11.

A manufacturing method for the above LED is different from that of the first embodiment in that after removing the n-type GaAs substrate (see FIG. 6A), the epitaxial layers 2 to 6 are partially removed by etching to partially expose the p-type GaP contact layer 7, and the p-type electrode 10 is then formed on the exposed p-type GaP contact layer 7.

In the second embodiment, the n-type GaP transmissive substrate 109 is used, but a non-doped transmissive substrate shaped like the n-type GaP transmissive substrate 109 may be used, or a p-type transmissive substrate shaped like the n-type GaP transmissive substrate 109 may be used.

Furthermore, various modifications described in relation to the first embodiment may be applied to the second embodiment as appropriate.

In the second embodiment, an attaching method similar to that of the first embodiment (FIG. 8) is used.

In the first and second embodiments, the conductivity types of the layers and substrates may be reversed.

The first embodiment and the second embodiment may be combined as appropriate.

It is needless to say that the present invention is applicable to not only a light-emitting diode having a AlGaInP 4-element luminous layer but also a semiconductor light-emitting device having a luminous layer made of semiconductor crystal.

Furthermore, materials and techniques to be used in the present invention are not limited to those of the first and second embodiments, and any suitable material and technique may be used in the present invention.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor light-emitting device, comprising:
a first conductivity type semiconductor layer;
a luminous layer formed on the first conductivity type semiconductor layer;
a second conductivity type semiconductor layer formed on the luminous layer; and
a transmissive semiconductor layer which is formed on the second conductivity type semiconductor layer and is pervious to light coming from the luminous layer, wherein
the second conductivity type semiconductor layer and the transmissive semiconductor layer have different carrier concentrations, and the carrier concentration of the second conductivity type semiconductor layer is higher than the carrier concentration of the transmissive semiconductor layer.

2. A semiconductor light-emitting device as claimed in claim 1, wherein the carrier concentration of the transmissive semiconductor layer is 2.5×10¹⁸ cm⁻³ or less.

3. A semiconductor light-emitting device as claimed in claim 1, wherein the carrier concentration of the transmissive semiconductor layer is between 2.5×10¹⁷ cm⁻³ and 8.0×10¹⁷ cm⁻³, inclusive.

4. A semiconductor light-emitting device as claimed in claim 1, further comprising a second conductivity type intermediate layer disposed between the luminous layer and the second conductivity type semiconductor layer, wherein the carrier concentration of the second conductivity type semiconductor layer is higher than that of the second conductivity type intermediate layer.

5. A semiconductor light-emitting device as claimed in claim 1, wherein the transmissive semiconductor layer has a thickness of 0.5 μm or more.

6. A semiconductor light-emitting device as claimed in claim 1, further comprising a transmissive semiconductor substrate which is formed on the transmissive semiconductor layer and is pervious to light coming from the luminous layer, wherein at least one of the transmissive semiconductor layer and the transmissive semiconductor substrate is made of first conductivity type semiconductor.

7. A semiconductor light-emitting device as claimed in claim 1, wherein the first conductivity type semiconductor layer, the luminous layer, and the second conductivity type semiconductor layer each contain at least two of gallium, aluminum, indium, phosphorus, arsenic, zinc, tellurium, sulfur, nitrogen, silicon, carbon, and oxygen.

8. A semiconductor light-emitting device as claimed in claim 1, wherein the transmissive semiconductor layer has a thickness of 70 μm or more.

9. A semiconductor light-emitting device as claimed in claim 1, further comprising a transmissive semiconductor substrate which is formed on the transmissive semiconductor layer and is pervious to light coming from the luminous layer, wherein the transmissive semiconductor layer and the transmissive semiconductor substrate are of different conductivity types.

10. A method of manufacturing a semiconductor light-emitting device, comprising steps of:
fabricating a first wafer by stacking layers including at least a first conductivity type semiconductor layer, a luminous layer, and a second conductivity type semiconductor layer on a first conductivity type semiconductor substrate;
fabricating a second wafer by forming a transmissive semiconductor layer on a transmissive semiconductor substrate which is pervious to light coming from the luminous layer, said transmissive semiconductor layer having a carrier concentration lower than a carrier concentration of the second conductivity type semiconductor layer and being pervious to light coming from the luminous layer;
joining the second wafer to the first wafer by first placing the second wafer on the first wafer in such a manner that the transmissive semiconductor layer is opposed to the second conductivity type semiconductor layer and then heating the first and second wafers while pressing the second wafer against the first wafer; and
removing the first conductivity type semiconductor substrate.

11. A method of manufacturing a semiconductor light-emitting device as claimed in claim 11, wherein after joining the second wafer to the first wafer, the method further comprising a step of:
removing the transmissive semiconductor substrate.

12. A method of manufacturing a semiconductor light-emitting device as claimed in claim 10, wherein the step of fabricating a second wafer comprises forming the transmissive semiconductor layer by liquid phase epitaxy or a CVD method.
